(19) United States
(12) Patent Application Publication
(10) Pub. No.: US 2013/0093438 A1
(43) Pub. Date: Apr. 18, 2013

(54) PRESSURE-SENSITIVE ADHESIVE LAYER FOR TRANSPARENT CONDUCTIVE FILM, TRANSPARENT CONDUCTIVE FILM WITH PRESSURE-SENSITIVE ADHESIVE LAYER, TRANSPARENT CONDUCTIVE LAMINATE, AND TOUCH PANEL

(71) Applicants: Toshitsugu Hosokawa, Ibaraki-shi (JP); Kunihiro Inui, Ibaraki-shi (JP); Takaaki Ishii, Ibaraki-shi (JP); Masayuki Satake, Ibaraki-shi (JP); Ai Murakami, Ibaraki-shi (JP); Yuka Yamazaki, Ibaraki-shi (JP)

(72) Inventors: Toshitsugu Hosokawa, Ibaraki-shi (JP); Kunihiro Inui, Ibaraki-shi (JP); Takaaki Ishii, Ibaraki-shi (JP); Masayuki Satake, Ibaraki-shi (JP); Ai Murakami, Ibaraki-shi (JP); Yuka Yamazaki, Ibaraki-shi (JP)

(73) Assignee: NITTO DENKO CORPORATION, Ibaraki-shi, Osaka (JP)

(21) Appl. No.: 13/703,770

(22) PCT Filed: Jul. 22, 2011
(86) PCT No.: PCT/JP2011/066731

§ 371 Date: Dec. 12, 2012

(30) Foreign Application Priority Data
Jul. 30, 2010 (JP) 2010-172457

(51) Int. Cl. C09J 7/02; G01R 27/26

(52) U.S. Cl. CPC C09J 7/0217; G01R 27/2605
USPC 324/661; 428/220; 428/354

(57) ABSTRACT

A pressure-sensitive adhesive layer of the invention for transparent conductive film has a thickness of 10 μm to 100 μm, and is made from a water-dispersible acryl-based pressure-sensitive adhesive that is an aqueous dispersion containing a water-dispersible (meth)acryl-based polymer and a water-soluble basic component, wherein the water-dispersible (meth)acryl-based polymer comprises 100 parts by weight of an alkyl(meth)acrylate with an alkyl group of 4 to 14 carbon atoms, as a monomer unit, and 1 to 8 parts by weight of a carboxyl group-containing monomer as a copolymerized monomer unit, and the pressure-sensitive adhesive layer contains 200 ng to 500,000 ng of the water-soluble basic component per 1 cm² as determined by measurement of the pressure-sensitive adhesive layer. The pressure-sensitive adhesive layer can have satisfactory durability in a high-temperature or high-temperature, high-humidity environment and can suppress corrosion in a high-temperature, high-humidity environment.

### TECHNICAL FIELD

The invention relates to a pressure-sensitive adhesive layer for transparent conductive film and to a transparent conductive film with pressure-sensitive adhesive layer having the pressure-sensitive adhesive layer. The invention also relates to a transparent conductive laminate produced using the transparent conductive film with pressure-sensitive adhesive layer. The transparent conductive film with pressure-sensitive adhesive layer or the transparent conductive laminate may be subjected to a processing treatment as needed and then used to form a transparent electrode for a display such as a liquid crystal display or an electroluminescence display or a touch panel such as an optical, ultrasonic, capacitance, or resistive touch panel. The pressure-sensitive adhesive layer for transparent conductive film and other products according to the invention are suitable for use in touch panels.

### BACKGROUND ART

Concerning conventional transparent conductive thin film, the so-called conductive glass is well known, which includes a glass member and an indium oxide thin film formed thereon. Since the base member of the conductive glass is made of glass, however, it has low flexibility or workability and cannot preferably be used in some applications. In recent years, therefore, transparent conductive films, which has transparent conductive thin film, using various types of plastic films such as polyethylene terephthalate films as their substrates have been used, because of their advantages such as good impact resistance and light weight as well as flexibility and workability.

When used, the transparent conductive film forms a transparent conductive laminate, which includes a transparent plastic film substrate, a transparent conductive thin film formed of a metal oxide on one surface of the transparent plastic film substrate, and a transparent substrate bonded to the other surface of the transparent plastic film substrate with a pressure-sensitive adhesive layer interposed therebetween, wherein the pressure-sensitive adhesive layer forms a transparent conductive film with pressure-sensitive adhesive layer. Such a transparent conductive laminate is generally used to form an electrode plate for a resistive touch panel (Patent Document 1).

Resistive touch panels are excellent in terms of cost and accuracy. Unfortunately, as compared to other types, resistive touch panels have low transmittance, because of their structure having a film (electrode) and two glass sheets, and therefore, the part (frame) other than the effective screen is relatively wide in a resistive touch panel. Resistive touch panels also have disadvantages such as narrow operating temperature range and low resistance to degradation over time because they have a structure in which a film (electrode) is pushed down to make a short circuit. Capacitance touch panels have spread rapidly as a substitute for compensating for the disadvantages. Capacitance touch panels are used in applications where an increase in the area of the input screen or durability is highly required, such as cellular phone applications and car navigation applications. Also in capacitance touch panels, a transparent conductive film with pressure-sensitive adhesive layer is used to form an electrode plate. In capacitance touch panels, a laminate of a plurality of transparent conductive films with pressure-sensitive adhesive layer has been more often used.

A pressure-sensitive adhesive for use on the above transparent conductive film is required to have durability that can achieve satisfactory adhesion to prevent peeling or foaming in a high-temperature or high-temperature, high-humidity environment. For example, an acryl-based pressure-sensitive adhesive is used as such a pressure-sensitive adhesive, and in view of adhesion and other properties, an acryl-based polymer containing a carboxyl group component is used as a base polymer in such an acryl-based pressure-sensitive adhesive (Patent Document 2).

### PRIOR ART DOCUMENTS

### Patent Documents

Patent Document 1: JP-A-06-309990

Patent Document 2: JP-A-2009-242786

### SUMMARY OF THE INVENTION

### Problems to be Solved by the Invention

If the acryl-based pressure-sensitive adhesive containing an acryl-based polymer is used to form a pressure-sensitive adhesive layer for transparent conductive film, the carboxyl group component in the acryl-based polymer can corrode the metal. For example, when a laminate of a plurality of transparent conductive films with pressure-sensitive adhesive layer is used, the problem of the corrosion of the transparent conductive thin film made of a metal oxide can significantly occur because the pressure-sensitive adhesive layer is in direct contact with the transparent conductive thin film. A particular problem is the corrosion of the transparent conductive thin film in a high-temperature, high-humidity environment.

An object of the invention is to provide a pressure-sensitive adhesive layer for transparent conductive film, which can have satisfactory durability in a high-temperature or high-temperature, high-humidity environment and can suppress corrosion in a high-temperature, high-humidity environment.

Another object of the invention is to provide a transparent conductive film with pressure-sensitive adhesive layer including a transparent plastic film substrate, a transparent conductive thin film formed of a metal oxide on one surface of the substrate, and the pressure-sensitive adhesive layer provided on the other surface of the transparent plastic film substrate, to provide a transparent conductive laminate produced using such a transparent conductive film with pressure-sensitive adhesive layer, and to provide a touch panel produced using such a transparent conductive film with pressure-sensitive adhesive layer or such a transparent conductive laminate.

### Means for Solving the Problems

As a result of intense investigations to solve the problems, the inventors have made the invention, based on the finding that the objects are achieved with a pressure-sensitive adhesive layer for transparent conductive film or others described below.

The invention relates to a pressure-sensitive adhesive layer for transparent conductive film, wherein

the pressure-sensitive adhesive layer has a thickness of 10 μm to 100 μm, and

the pressure-sensitive adhesive layer is made from a water-dispersible acryl-based pressure-sensitive adhesive that is an aqueous dispersion containing a water-dispersible (meth)acryl-based polymer and a water-soluble basic component, wherein the water-dispersible (meth)acryl-based polymer includes 100 parts by weight of an alkyl(meth)acrylate with an alkyl group of 4 to 14 carbon atoms, as a monomer unit, and 1 to 8 parts by weight of a carboxyl group-containing monomer as a copolymerized monomer unit, and

the pressure-sensitive adhesive layer contains 200 ng to 500,000 ng of the water-soluble basic component per 1 cm² as determined by measurement of the pressure-sensitive adhesive layer.

The pressure-sensitive adhesive layer for transparent conductive film preferably contains more than 2,000 ng of the water-soluble basic component per 1 cm² as determined by measurement of the pressure-sensitive adhesive layer.

In the pressure-sensitive adhesive layer for transparent conductive film, the water-soluble basic component is preferably ammonia.

In the pressure-sensitive adhesive layer for transparent conductive film, the water-dispersible (meth)acryl-based polymer preferably further includes 0.5 to 5 parts by weight of a phosphate group-containing monomer as a monomer unit based on 100 parts by weight of the alkyl(meth)acrylate.

The pressure-sensitive adhesive layer for transparent conductive film is preferably used for a transparent conductive film of a capacitance touch panel.

The invention also relates to a transparent conductive film with pressure-sensitive adhesive layer, including:

a first transparent plastic film substrate;

a transparent conductive thin film formed of a metal oxide on one surface of the substrate; and

the above pressure-sensitive adhesive layer provided on another surface of the first transparent plastic film substrate.

The transparent conductive film with pressure-sensitive adhesive layer may further includes at least one undercoat layer, wherein the transparent conductive thin film is provided on the first transparent plastic film substrate with the undercoat layer interposed therebetween.

The transparent conductive film with pressure-sensitive adhesive layer may further includes an oligomer blocking layer, wherein the pressure-sensitive adhesive layer is provided on the first transparent plastic film substrate with the oligomer blocking layer interposed therebetween.

The transparent conductive film with pressure-sensitive adhesive layer is preferably used for in a capacitance touch panel.

The invention also relates to a transparent conductive laminate, including:

the above transparent conductive film with pressure-sensitive adhesive layer; and

a second transparent plastic film substrate bonded to the pressure-sensitive adhesive layer of the transparent conductive film with pressure-sensitive adhesive layer.

The transparent conductive laminate is preferably used for in a capacitance touch panel.

The invention also relates to a touch panel, including an electrode plate including the above transparent conductive film with pressure-sensitive adhesive layer or the above transparent conductive laminate.

The touch panel is preferably used for in a capacitance touch panel.

### Effect of the Invention

The pressure-sensitive adhesive layer of the invention for transparent conductive film is applied to a transparent conductive film including a film substrate and a transparent conductive thin film formed of a metal oxide on one surface of the film substrate. A transparent conductive film with pressure-sensitive adhesive layer is formed by providing the pressure-sensitive adhesive layer on the other surface of the transparent conductive film where the transparent conductive thin film is not provided. The pressure-sensitive adhesive layer of the invention for transparent conductive film has a specific thickness and is made from a water-dispersible acryl-based pressure-sensitive adhesive containing a specific amount of a water-soluble basic component and a (meth)acryl-based polymer containing a specific amount of a carboxyl group-containing monomer as a monomer unit.

The water-dispersible acryl-based pressure-sensitive adhesive contains, as a base polymer, a water-dispersible (meth)acryl-based polymer including a carboxyl group-containing monomer unit. Therefore, the pressure-sensitive adhesive layer maintains adhesion and high cohesive strength properties, has good durability, and is prevented from causing foaming or peeling in a high-temperature or high-temperature, high-humidity environment. On the other hand, the carboxyl group can produce an acid atmosphere, for example, which may corrode a transparent conductive thin film (metal oxide film). However, since the pressure-sensitive adhesive layer of the invention contains a water-soluble basic component, the carboxyl group can be efficiently neutralized with the water-soluble basic component, so that the corrosion can be suppressed in a high-temperature, high-humidity environment. In other words, the water-dispersible acryl-based pressure-sensitive adhesive contains a water-soluble basic component in addition to an aqueous dispersion containing a (meth)acryl-based polymer, which is a pressure-sensitive adhesive polymer, dispersed in the form of fine particles in water, and the water-soluble basic component can efficiently neutralize the carboxyl groups, which is a cause of corrosion, on the surface of the fine particles.

Therefore, the pressure-sensitive adhesive layer of the invention for transparent conductive film, which maintains adhesion and cohesive strength, can have satisfactory durability in a high-temperature or high-temperature, high-humidity environment, and can suppress corrosion. For example, even when the pressure-sensitive adhesive layer is used in direct contact with a transparent conductive thin film to form a laminate of transparent conductive films with pressure-sensitive adhesive layer, the pressure-sensitive adhesive layer can suppress the corrosion of the transparent conductive thin film and therefore is useful to form an electrode plate for a capacitance touch panel. When a pressure-sensitive adhesive layer is made from a solvent-type acryl-based pressure-sensitive adhesive, a crosslinking agent such as a polyfunctional isocyanate or a peroxide is needed to maintain durability such as heat resistance. In contrast, even when produced with no crosslinking agent, the pressure-sensitive adhesive layer of the invention made from the water-dispersible acryl-based pressure-sensitive adhesive has high cohesive strength in particles, which is also preferred because discoloration hardly occurs due to a crosslinking agent so that transparency can be easily maintained and that a neutral hue can be obtained.

### BRIEF DESCRIPTION OF THE DRAWINGS

FIG. 1 is a cross-sectional view showing an example of the transparent conductive film with pressure-sensitive adhesive layer of the invention;

FIG. 2 is a cross-sectional view showing an example of the transparent conductive film with pressure-sensitive adhesive layer of the invention;

FIG. 3 is a cross-sectional view showing an example of the transparent conductive laminate of the invention;

FIG. 4 is a cross-sectional view showing an example of the transparent conductive laminate of the invention.

### MODE FOR CARRYING OUT THE INVENTION

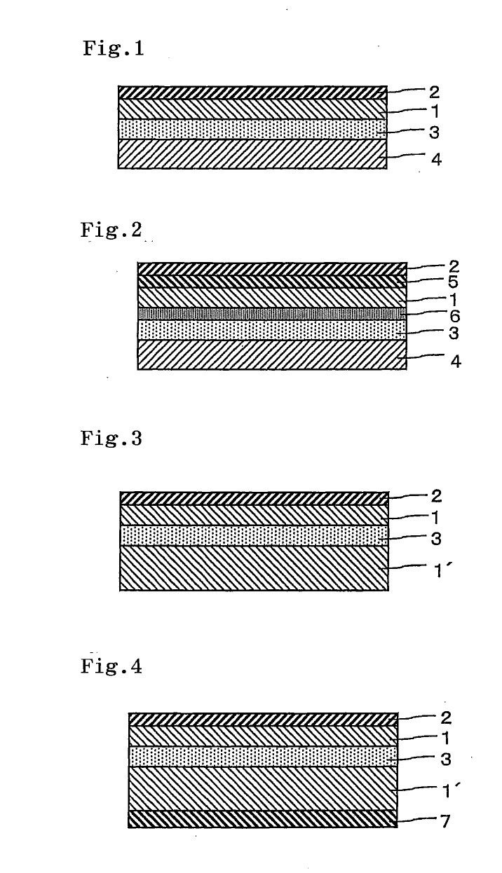

The pressure-sensitive adhesive layer for transparent conductive film and the transparent conductive film with the pressure-sensitive adhesive layer of the inventions are described below with reference to the FIGS. 1, 2. FIG. 1 is a cross-sectional view showing an example of the transparent conductive film with the pressure-sensitive adhesive layer of the invention. The transparent conductive film with the pressure-sensitive adhesive layer shown in FIG. 1 includes a first transparent plastic film substrate 1, a transparent conductive thin film 2 provided on one side of the first transparent plastic substrate 1, and a pressure-sensitive adhesive layer 3 (the pressure-sensitive adhesive layer for transparent conductive film) provided on the other side of the first transparent plastic substrate 1. A release sheet 4 is provided on the pressure-sensitive adhesive layer 3.

FIG. 2 shows another example including the structure of the transparent conductive film with the pressure-sensitive adhesive layer shown in FIG. 1 and an undercoat layer 5 interposed between one side of the first transparent plastic film substrate 1 and the transparent conductive thin film 2. While the undercoat layer 5 shown in FIG. 2 is a single layer, the undercoat layer 5 may be a multilayered structure. The pressure-sensitive adhesive layer 3 is provided on the other surface of the film substrate 1, on which the transparent conductive thin film 2 is formed, with an oligomer blocking layer 6 interposed therebetween. A release film 4 is provided on the pressure-sensitive adhesive layer 3. While the structure of FIG. 2 further includes the undercoat layer 5 and the oligomer blocking layer 6 in addition to the structure of FIG. 1, the transparent conductive film with pressure-sensitive adhesive layer of the invention may have the structure including the undercoat layer 5 or the oligomer blocking layer 6 in addition to the structure of FIG. 1.

First, a description is given of the pressure-sensitive adhesive layer 3 of the invention for transparent conductive film.

The pressure-sensitive adhesive layer 3 of the invention for transparent conductive film is made from a water-dispersible acryl-based pressure-sensitive adhesive. The water-dispersible acryl-based pressure-sensitive adhesive contains an aqueous dispersion containing a (meth)acryl-based polymer dispersed in water, in which the (meth)acryl-based polymer includes: an alkyl(meth)acrylate with an alkyl group of 4 to 14 carbon atoms as a principal monomer unit; and a carboxyl group-containing monomer as a copolymerized monomer unit in an amount of 1 to 8 parts by weight based on 100 parts by weight of the alkyl(meth)acrylate with an alkyl group of 4 to 14 carbon atoms. The (meth)acryl-based polymer may contain an alkyl(meth)acrylate with an alkyl group of 4 to 14 carbon atoms as a monomer unit in an amount of 60% by weight or more, preferably 70% by weight or more, more preferably 80% by weight or more, even more preferably 90% by weight or more, based on the total amount of all monomer units forming the (meth)acryl-based polymer.

For example, the (meth)acryl-based polymer, which is a base polymer in the water-dispersible acryl-based pressure-sensitive adhesive, can be obtained in the form of a copolymer emulsion by emulsion polymerization of a monomer composition containing 100 parts by weight of an alkyl(meth)acrylate with an alkyl group of 4 to 14 carbon atoms and 1 to 8 parts by weight of a carboxyl group-containing monomer in the presence of an emulsifying agent and a radical polymerization initiator. The term “alkyl(meth)acrylate” refers to alkyl acrylate and/or alkyl methacrylate, and “(meth)” is used in the same meaning in the description.

The alkyl group of 4 to 14 carbon atoms in the alkyl(meth)acrylate may be any of various straight or branched chain alkyl groups. Examples of the alkyl(meth)acrylate include n-butyl(meth)acrylate, isobutyl(meth)acrylate, sec-butyl(meth)acrylate, tert-butyl(meth)acrylate, n-pentyl(meth)acrylate, isopentyl(meth)acrylate, isoamyl(meth)acrylate, n-hexyl(meth)acrylate, heptyl(meth)acrylate, 2-ethylhexyl(meth)acrylate, isooctyl(meth)acrylate, n-nonyl(meth)acrylate, isononyl(meth)acrylate, n-decyl(meth)acrylate, isodecyl(meth)acrylate, n-dodecyl(meth)acrylate, isomyristyl(meth)acrylate, n-tridecyl(meth)acrylate, tetradecyl(meth)acrylate, etc. These maybe used alone or in any combination. In particular, n-butyl(meth)acrylate and 2-ethylhexyl(meth)acrylate are preferred.

Any monomer having a carboxyl group and an unsaturated double bond-containing polymerizable functional group such as a (meth)acryloyl group or a vinyl group may be used without restriction as the carboxyl group-containing monomer. Examples of the carboxyl group-containing monomer include acrylic acid, methacrylic acid, carboxyethyl(meth)acrylate, carboxypentyl(meth)acrylate, itaconic acid, maleic acid, fumaric acid, and crotonic acid. These may be used alone or in any combination. Among these, acrylic acid and methacrylic acid are preferred, and acrylic acid is particularly preferred.

The carboxyl group-containing monomer is used in an amount of 1 to 8 parts by weight based on 100 parts by weight of the alkyl(meth)acrylate. The amount of the carboxyl group-containing monomer is preferably from 2 to 7 parts by weight, more preferably from 3 to 6 parts by weight. If the amount of the carboxyl group-containing monomer is less than 1 part by weight, the pressure-sensitive adhesive layer for transparent conductive film can have low adhesion, or the pressure-sensitive adhesive itself can have low cohesive strength, which can easily cause foaming or peeling in a high-temperature or high-temperature, high-humidity environment. In such a case, the aqueous dispersion can also have low stability, so that coating appearance degradation can easily occur due to aggregates. On the other hand, if the amount is more than 8 parts by weight, aqueous solution polymerization can occur at the same time in the preparation of the aqueous dispersion, so that during the polymerization, the stability of the dispersion can significantly decrease or the viscosity of the aqueous dispersion can significantly increase, which can affect coating and therefore is not preferred.

Beside the alkyl(meth)acrylate and the carboxyl group-containing monomer, a copolymerizable monomer copolymerizable with the alkyl(meth)acrylate and the carboxyl group-containing monomer may also be used to form the (meth)acryl-based polymer for the purpose of improving the adhesion of the pressure-sensitive adhesive layer 3 to the substrate, improving the initial tackiness of the pressure-sensitive adhesive layer 3 to an adherend, and controlling the refractive index of the pressure-sensitive adhesive layer 3.

The copolymerizable monomer may be of any type having an unsaturated double bond-containing polymerizable functional group such as a (meth)acryloyl group or a vinyl group, examples of which include an alkyl(meth)acrylate having an alkyl group of 1 to 3 carbon atoms or 15 or more carbon atoms; alicyclic hydrocarbon esters of (meth)acrylic acid, such as cyclohexyl(meth)acrylate, bornyl(meth)acrylate, and isobornyl(meth)acrylate; aryl(meth)acrylate such as phenyl(meth)acrylate; vinyl esters such as vinyl acetate and vinyl propionate; styrene monomers such as styrene; epoxy group-containing monomers such as glycidyl(meth)acrylate and methylglycidyl(meth)acrylate; hydroxyl group-containing monomers such as 2-hydroxyethyl acrylate and 2-hydroxypropyl acrylate; nitrogen atom-containing monomers such as (meth)acrylamide, N,N-dimethyl(meth)acrylamide, N,N-diethyl(meth)acrylamide, N-isopropyl(meth)acrylamide, N-butyl(meth)acrylamide, N-methylol(meth)acrylamide, N-methylolpropane(meth)acrylamide, (meth)acryloylmorpholine, aminoethyl(meth)acrylate, N,N-dimethylaminoethyl(meth)acrylate, and tert-butylaminoethyl(meth)acrylate; alkoxy group-containing monomers such as methoxyethyl(meth)acrylate and ethoxyethyl(meth)acrylate; cyano group-containing monomers such as acrylonitrile and methacrylonitrile; functional monomers such as 2-methacryloyloxyethyl isocyanate; olefin monomers such as ethylene, propylene, isoprene, butadiene, and isobutylene; vinyl ether monomers such as vinyl ether; halogen atom-containing monomers such as vinyl chloride; and other monomers including vinyl group-containing heterocyclic compounds such as N-vinylpyrrolidone, N-(1-methylvinyl)pyrrolidone, N-vinylpyridine, N-vinylpiperidone, N-vinylpyrimidine, N-vinylpiperazine, N-vinylpyrazine, N-vinylpyrrole, N-vinylimidazole, N-vinyloxazole, and N-vinylmorpholine, and N-vinylcarboxylic acid amides.

Examples of the copolymerizable monomer also include maleimide monomers such as N-cyclohexylmaleimide, N-isopropylmaleimide, N-laurylmaleimide, and N-phenylmaleimide; itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide monomers such as N-(meth)acryloyloxymethylenesuccinimide, N-(meth)acryloyl-6-oxyhexamethylenesuccinimide, and N-(meth)acryloyl-8-oxyoctamethylenesuccinimide; and sulfonic acid group-containing monomers such as styrenesulfonic acid, allylsulfonic acid, 2-(meth)acrylamido-2-methylpropanesulfonic acid, (meth)acrylamidopropanesulfonic acid, sulfopropyl(meth)acrylate, and (meth)acryloyloxynaphthalenesulfonic acid.

The copolymerizable monomer may also be a phosphate group-containing monomer. For example, the phosphate group-containing monomer may be a phosphate group-containing monomer represented by formula (1) below or a salt thereof.

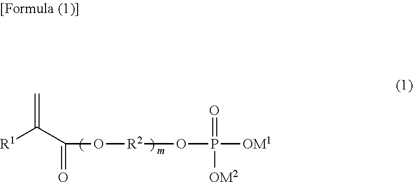

In formula (1), R² represents a hydrogen atom or a methyl group, R² represents an alkylene group of 1 to 4 carbon atoms, m represents an integer of 2 or more, and M¹ and M² each independently represent a hydrogen atom or a cation.

In formula (1), m is 2 or more, preferably 4 or more, generally 40 or less, and m represents the degree of polymerization of the oxyalkylene groups. The polyoxyalkylene group may be a polyoxyethylene group or a polyoxypropylene group, and these polyoxyalkylene groups may comprise random, block, or graft units. The cation of the salt of the phosphate group is typically, but not limited to, an inorganic cation such as an alkali metal such as sodium or potassium or an alkaline-earth metal such as calcium or magnesium, or an organic cation such as a quaternary amine.

Examples of the copolymerizable monomer also include glycol acrylate monomers such as polyethylene glycol(meth)acrylate, polypropylene glycol(meth)acrylate, methoxyethylene glycol(meth)acrylate, and methoxypolypropylene glycol(meth)acrylate; and other monomers such as acrylic ester monomers containing a heterocyclic ring or a halogen atom, such as tetrahydrofurfuryl(meth)acrylate and fluoro(meth)acrylate.

A polyfunctional monomer may also be used as the copolymerizable monomer for a purpose such as control of the gel fraction of the water-dispersible acryl-based pressure-sensitive adhesive. The polyfunctional monomer may be a compound having two or more unsaturated double bonds such as those in (meth)acryloyl groups or vinyl groups. Examples that may also be used include (meth)acrylate esters of polyhydric alcohols, such as (mono or poly)alkylene glycol di(meth)acrylates including (mono or polyethylene glycol di(meth)acrylates such as ethylene glycol di(meth)acrylate, diethylene glycol di(meth)acrylate, triethylene glycol di(meth)acrylate, trimethylolpropane tri(meth)acrylate, and tetraethylene glycol di(meth)acrylate, (mono or poly)propylene glycol di(meth)acrylate such as propylene glycol di(meth)acrylate, neopentyl glycol di(meth)acrylate, 1,6-hexanediol di(meth)acrylate, pentaerythritol di(meth)acrylate, trimethylolpropane tri(meth)acrylate, pentaerythritol tri(meth)acrylate, and dipentaerythritol hexa(meth)acrylate; polyfunctional vinyl compounds such as divinylbenzene; and compounds having a reactive unsaturated double bond, such as allyl(meth)acrylate and vinyl(meth)acrylate. The polyfunctional monomer may also be a compound having a polyester, epoxy or urethane skeleton to which two or more unsaturated double bonds are added in the form of functional groups such as (meth)acryloyl groups or vinyl groups in the same manner as the monomer component, such as polyester(meth)acrylate, epoxy(meth)acrylate, or urethane(meth)acrylate.

The content of the copolymerizable monomer other than the carboxyl group-containing monomer is preferably 40 parts by weight or less, more preferably 30 parts by weight or less, even more preferably 20 parts by weight or less, still more preferably 10 parts by weight or less, based on 100 parts by weight of the alkyl(meth)acrylate with an alkyl group of 4 to 14 carbon atoms. If the content of the copolymerizable monomer is too high, the pressure-sensitive adhesive layer 3 of the invention made from the water-dispersible acryl-based pressure-sensitive adhesive may have degraded pressure-sensitive adhesive properties such as degraded adhesion to various adherends such as glass, films, and transparent conductive thin films.

Among copolymerizable monomers other than the carboxyl group-containing monomer, a phosphate group-containing monomer is preferably used so that the aqueous dispersion (emulsion or the like) can be stabilized or the pressure-sensitive adhesive layer 3 made from the aqueous dispersion can have reliable adhesion to various adherends. When the copolymerizable monomer is a phosphate group-containing monomer, the content of the phosphate group-containing monomer is preferably from 0.5 to 5 parts by weight based on 100 parts by weight of the alkyl(meth)acrylate. The content is more preferably from 1 to 4 parts by weight, even more preferably from 1 to 3 parts by weight. When the phosphate group-containing monomer is used within these ranges, foaming, peeling, or yellowing in a high-temperature or high-temperature, high-humidity environment, and corrosion of the transparent conductive thin film in a high-temperature, high-humidity environment can be further suppressed.

Emulsion polymerization of the monomer components may be performed by a conventional method including emulsifying the monomer components in water and then subjecting the emulsion to emulsion polymerization. This method prepares an aqueous dispersion containing a (meth)acryl-based polymer dispersed as a base polymer. In the emulsion polymerization, for example, the monomer components, an emulsifying agent, and a radical polymerization initiator, and optionally a chain transfer agent or the like are mixed in water as appropriate. More specifically, for example, a known emulsion polymerization method may be employed, such as a batch mixing method (batch polymerization method), a monomer dropping method, or a monomer emulsion dropping method. In a monomer dropping method, continuous dropping or divided dropping is appropriately selected. These methods may be appropriately combined. While reaction conditions and so on may be appropriately selected, for example, the polymerization temperature is preferably from about 20 to about 90° C.

The emulsifying agent to be used may be, but not limited to, any of various emulsifying agents commonly used in emulsion polymerization. Examples include anionic emulsifying agents such as sodium lauryl sulfate, ammonium lauryl sulfate, sodium dodecylbenzenesulfonate, sodium polyoxyethylene lauryl sulfate, sodium polyoxyethylene alkyl ether sulfate, ammonium polyoxyethylene alkyl phenyl ether sulfate, sodium polyoxyethylene alkyl phenyl ether sulfate, and sodium polyoxyethylene alkyl sulfosuccinate; and nonionic emulsifying agents such as polyoxyethylene alkyl ether, polyoxyethylene alkyl phenyl ether, polyoxyethylene fatty acid ester, and polyoxyethylene-polyoxypropylene block polymers. Examples also include radically-polymerizable emulsifying agents produced by introducing a radically-polymerizable functional group (radically-reactive group) such as a propenyl group or an allyl ether group into the above anionic or nonionic emulsifying agents. These emulsifying agents may be appropriately used alone or in combination of two or more. Among these emulsifying agents, radically-polymerizable emulsifying agents having a radically-polymerizable functional group are preferably used in view of the stability of the aqueous dispersion (emulsion) or the durability of the pressure-sensitive adhesive layer 3.

The content of the emulsifying agent is typically from about 0.1 to about 5 parts by weight, preferably from 0.4 to 3 parts by weight, based on 100 parts by weight of the monomer components including the alkyl(meth)acrylate as a main component. Setting the emulsifying agent content in this range makes it possible to improve not only water resistance and adhesive properties but also other properties such as polymerization stability and mechanical stability.

The radical polymerization initiator may be, but not limited to, any known radical polymerization initiator commonly used in emulsion polymerization. Examples include azo initiators such as 2,2′-azobisisobutylonitrile, 2,2′-azobis(2-methylpropionamidine)disulfate, 2,2′-azobis(2-methylpropionamidine)dihydrochloride, 2,2′-azobis(2-amidinopropane)dihydrochloride, and 2,2′-azobis[2-(2-imidazoline-2-yl)propane]dihydrochloride; persulfate initiators such as potassium persulfate and ammonium persulfate; peroxide initiators such as benzoyl peroxide, tert-butyl hydroperoxide, and hydrogen peroxide; substituted ethane initiators such as phenyl-substituted ethane; and carbonyl initiators such as aromatic carbonyl compounds. These polymerization initiators may be appropriately used alone or in any combination. The content of the radical polymerization initiator is typically from about 0.02 to about 0. 5 parts by weight, preferably from 0.08 to 0.3 parts by weight, based on 100 parts by weight of the monomer components, while it is appropriately selected. If it is less than 0.02 parts by weight, the radical polymerization initiator may be less effective. If it is more than 0.5 parts by weight, the water-dispersible (meth)acryl-based polymer may have a reduced molecular weight, so that the water-dispersible acryl-based pressure-sensitive adhesive may have reduced durability.

A chain transfer agent is optionally used to control the molecular weight of the water-dispersible (meth)acryl-based polymer. In general, chain transfer agents commonly used in emulsion polymerization are used. Examples include 1-dodecanthiol, mercaptoacetic acid, 2-mercaptoethanol, 2-ethylhexyl thioglycolate, 2,3-dimercapto-1-propanol, mercaptopropionic acid esters, and other mercaptans. These chain transfer agents may be appropriately used alone or in any combination. For example, the content of the chain transfer agent is from 0.001 to 0.3 parts by weight based on 100 parts by weight of the monomer components.

According to the emulsion polymerization described above, the water-dispersible (meth)acryl-based polymer can be prepared in the form of an aqueous dispersion (emulsion). The average particle size of such a water-dispersible (meth)acryl-based polymer is typically controlled in the range of 0.05 to 3 μm, preferably in the range of 0.05 to 1 μm. If the average particle size is less than 0.05 μm, the water-dispersible acryl-based pressure-sensitive adhesive may have increased viscosity, and if it is more than 1 μm, adhesiveness between particles may decrease so that cohesive strength may decrease.

In general, the water-dispersible (meth)acryl-based polymer according to the invention preferably has a weight average molecular weight of 1,000,000 or more. In particular, the weight average molecular weight is preferably from 1,000,000 to 4,000,000 in view of heat resistance or moisture resistance. A weight average molecular weight of less than 1,000,000 is not preferred, because with such a molecular weight, heat resistance or moisture resistance may decrease. The pressure-sensitive adhesive obtained by the emulsion polymerization is preferred because the polymerization mechanism can produce very high molecular weight. It should be noted, however, that the pressure-sensitive adhesive obtained by the emulsion polymerization generally has a high gel content and cannot be subjected to GPC (gel permeation chromatography) measurement, which means that it is often difficult to identify the molecular weight by actual measurement.

According to the invention, the aqueous dispersion for the water-dispersible acryl-based pressure-sensitive adhesive contains a water-soluble basic component in addition to the water-dispersible (meth)acryl-based polymer. The water-soluble basic component is a compound capable of forming a salt upon an acid-base neutralization reaction with the carboxyl group of the water-dispersible (meth)acryl-based polymer. In general, the water-soluble basic component is a compound that exhibits alkalinity in an aqueous solution when dissolved in water. Examples of the water-soluble basic component include alkanolamines such as 2-dimethylaminoethanol, diethanolamine, triethanolamine, and aminomethyl propanol; alkylamines such as trimethylamine, triethylamine, and butylamine; polyalkylene polyamines such as ethylenediamine, diethylenetriamine, triethylenetetramine, and tetraethylenepentamine; and other organic amine compounds such as ethyleneimine, polyethyleneimine, imidazole, 2-methylimidazole, pyridine, aniline, and morpholine. Examples of the water-soluble basic component further include inorganic basic compounds such as alkali metal hydroxides including sodium hydroxide and potassium hydroxide; and alkaline-earth metal hydroxides including barium hydroxide, calcium hydroxide, and aluminum hydroxide; and ammonia. Among these, ammonia is preferred in view of the effect of stabilizing the aqueous dispersion by the addition of the water-soluble basic component for the neutralization, the easiness of controlling viscosity to an appropriate level where streaks or unevenness does not occur when the water-dispersible acryl-based pressure-sensitive adhesive is applied, and the balance between the corrosion resistance and the durability of the pressure-sensitive adhesive layer 3 after applying and drying.

The amount of the water-soluble basic component is so controlled that the amount of the water-soluble basic component determined by the measurement of the pressure-sensitive adhesive layer 3 falls within the range of 200 to 500,000 ng per 1 cm². If the amount of the water-soluble basic component is less than 200 ng, the anti-corrosion effect will be insufficient. From this point of view, the amount of the water-soluble basic component is preferably 500 ng or more, more preferably 700 ng or more. In particular, it is preferably used in an amount of more than 2,000 ng. On the other hand, if the amount of the water-soluble basic component is more than 500,000 ng, it can excessively increase the viscosity of the aqueous dispersion when it is added to neutralize the aqueous dispersion, so that the appearance of the pressure-sensitive adhesive layer 3 formed by coating can be degraded. In this case, water resistance may also tend to decrease. From these points of view, the amount of the water-soluble basic component is preferably 250,000 ng or less. When a volatile compound such as ammonia is used as the water-soluble basic component, the drying temperature in the process of applying and drying the water-dispersible acryl-based pressure-sensitive adhesive that is an aqueous dispersion containing the water-soluble basic component and the (meth)acryl-based polymer dispersed in water should be set relatively low so that a relatively large amount of the water-soluble basic component can be left, which can cause a reduction in drying efficiency (the time required for drying can increase). From this point of view, when a volatile compound such as ammonia is used as the water-soluble basic component, the amount of the water-soluble basic component is preferably 50,000 ng or less, more preferably 10,000 ng or less, even more preferably 8,000 ng or less, still more preferably 6,000 ng or less.

The amount of the water-soluble basic component determined by the measurement of the pressure-sensitive adhesive layer 3 can be controlled by controlling the amount of the water-soluble basic component added to the aqueous dispersion in the process of preparing the water-dispersible acryl-based pressure-sensitive adhesive, by controlling the drying conditions in the process of applying and drying the water-dispersible acryl-based pressure-sensitive adhesive, or by controlling the thickness of the pressure-sensitive adhesive layer 3.

The added amount of the water-soluble basic component is preferably such that the aqueous dispersion containing the water-soluble basic component and the (meth)acryl-based polymer dispersed in water has a pH of 7 to 12, more preferably 8 to 11. If the pH is less than 7, the final amount of the water-soluble basic component in the pressure-sensitive adhesive layer may be insufficient, which is not preferred for the prevention of corrosion. If the pH is more than 12, the stability of the aqueous dispersion may be degraded.

The amount of the water-soluble basic component can also be controlled by controlling the drying conditions and the thickness of the pressure-sensitive adhesive layer in the process of forming the pressure-sensitive adhesive layer, in which the drying conditions and the thickness of the pressure-sensitive adhesive layer can be controlled as appropriate depending on the type of the water-soluble basic component used. For example, when the water-soluble basic component used is a material easy to evaporate during the drying process, such as ammonia or an alkylamine such as triethylamine, the amount of the water-soluble basic component determined by the measurement of the pressure-sensitive adhesive layer can be controlled by setting the pH relatively high, setting the drying conditions at relatively low level in the applying and drying process, or making the pressure-sensitive adhesive layer relatively thick. On the other hand, for example, when the water-soluble basic component used is a material hard to evaporate during the drying process, such as an alkali metal hydroxide such as sodium hydroxide or potassium hydroxide, or an amine, the amount of the water-soluble basic component determined by the measurement of the pressure-sensitive adhesive layer can be controlled by setting the pH relatively low or making the pressure-sensitive adhesive layer relatively thin.

A description is given of an example in which ammonia or sodium hydroxide is used as the water-soluble basic component. Ammonia may be used in the form of an ammonia water, and in general, the ammonia water is preferably added in an amount containing about 0.1 to about 20 parts by weight of ammonia, more preferably 0.2 to 5 parts by weight of ammonia, based on 100 parts by weight of the solid in the aqueous dispersion containing the (meth)acryl-based polymer. Sodium hydroxide may be used in the form of an aqueous sodium hydroxide solution, and in general, the aqueous sodium hydroxide solution is preferably added in an amount containing about 0.05 to about 5 parts by weight of sodium hydroxide, more preferably 0.1 to 3 parts by weight of sodium hydroxide, based on 100 parts by weight of the solid in the aqueous dispersion containing the (meth)acryl-based polymer.

To improve adhesion under high-temperature, high-humidity conditions, any of various silane coupling agents may be added to the water-dispersible acryl-based pressure-sensitive adhesive for use in forming the pressure-sensitive adhesive layer 3 of the invention. Silane coupling agents having any appropriate functional group maybe used. Examples of such a functional group include vinyl, epoxy, amino, mercapto, (meth)acryloxy, acetoacetyl, isocyanate, styryl, and polysulfide groups. Examples of the silane coupling agent include a vinyl group-containing silane coupling agent such as vinyltriethoxysilane, vinyltripropoxysilane, vinyltriisopropoxysilane, or vinyltributoxysilane; an epoxy group-containing silane coupling agent such as γ-glycidoxypropyltrimethoxysilane, γ-glycidoxypropyltriethoxysilane, 3-glycidoxypropylmethyldiethoxysilane, or 2-(3,4-epoxycyclohexyl)ethyltrimethoxysilane; an amino group-containing silane coupling agent such as γ-aminopropyltrimethoxysilane, N-β-(aminoethyl)-γ-aminopropylmethyldimethoxysilane, N-(2-aminoethyl)3-aminopropylmethyldimethoxysilane, γ-triethoxysilyl-N-(1,3-dimethylbutylidene)propylamine, or N-phenyl-γ-aminopropyltrimethoxysilane; a mercapto group-containing silane coupling agent such as γ-mercaptopropylmethyldimethoxysilane, a styryl group-containing silane coupling agent such as p-styryltrimethoxysilane; a (meth)acrylic group-containing silane coupling agent such as γ-acryloxypropyltrimethoxysilane or γ-methacryloxypropyltriethoxysilane; an isocyanate group-containing silane coupling agent such as 3-isocyanatepropyltriethoxysilane; and a polysulfide group-containing silane coupling agent such as bis(triethoxysilylpropyl)tetrasulfide.

Among the silane coupling agents, silane coupling agents having a radically polymerizable group copolymerizable with the above monomers, such as a vinyl group, a (meth)acryloxy group, or a styryl group are preferred, and in view of reactivity, silane coupling agents having a (meth)acryloxy group are particularly preferred. For example, include (meth)acryloyloxyalkyl-trialkoxysilanes such as (meth)acryloyloxymethyl-trimethoxysilane, (meth)acryloyloxymethyl-triethoxysilane, 2-(meth)acryloyloxyethyl-trimethoxysilane, 2-(meth)acryloyloxyethyl-triethoxysilane, 3-(meth)acryloyloxypropyl-trimethoxysilane, 3-(meth)acryloyloxypropyl-triethoxysilane, 3-(meth)acryloyloxypropyl-tripropoxysilane, 3-(meth)acryloyloxypropyl-triisopropoxysilane, and 3-(meth)acryloyloxypropyl-tributoxysilane; (meth)acryloyloxyalkyl-alkyldialkoxysilanes such as (meth)acryloyloxymethyl-methyldimethoxysilane, (meth)acryloyloxymethyl-methyldiethoxysilane, 2-(meth)acryloyloxyethyl-methyldimethoxysilane, 2-(meth)acryloyloxyethyl-methyldiethoxysilane, 3-(meth)acryloyloxypropyl-methyldimethoxysilane, 3-(meth)acryloyloxypropyl-methyldiethoxysilane, 3-(meth)acryloyloxypropyl-methyldipropoxysilane, 3-(meth)acryloyloxypropyl-methyldiisopropoxysilane, 3-(meth)acryloyloxypropyl-methyldibutoxysilane, 3-(meth)acryloyloxypropyl-ethyldimethoxysilane, 3-(meth)acryloyloxypropyl-ethyldiethoxysilane, 3-(meth)acryloyloxypropyl-ethyldipropoxysilane, 3-(meth)acryloyloxypropyl-ethyldiisopropoxysilane, 3-(meth)acryloyloxypropyl-ethyldibutoxysilane, 3-(meth)acryloyloxypropyl-propyldimethoxysilane, and 3-(meth)acryloyloxypropyl-propyldiethoxysilane; and (meth)acryloyloxyalkyl-dialkyl(mono)alkoxysilanes corresponding to these monomers.

The silane coupling agents may be used alone or in combination of two or more. Based on 100 parts by weight of the (meth)acryl-based polymer, the total content of the silane coupling agent(s) is preferably 1 part by weight or less, more preferably from 0.01 to 1 part by weight, even more preferably from 0.02 to 0.6 parts by weight, still more preferably from 0.05 to 0.2 parts by weight. If the content of the silane coupling agent is more than 1 part by weight, part of the coupling agent may remain unreacted, which is not preferred in view of durability.

When the silane coupling agent is radically copolymerizable with the above monomers, it may be used as one of the monomers. In such a case, the content of the silane coupling agent is preferably from 0.005 to 0.2 parts by weight based on 100 parts by weight of the alkyl(meth)acrylate.

If necessary, the water-dispersible acryl-based pressure-sensitive adhesive of the invention may further appropriately contain any of various additives such as viscosity adjusting agent, releasing adjusting agent, crosslinking agents, tackifiers, plasticizers, softener, fillers including glass fibers, glass beads, metal power, or any other inorganic powder, pigments, colorants(pigments, dyes or the likes), pH adjusting agent(acid or base), antioxidants, and ultraviolet ray absorbing agents, without departing from the objects of the invention. These additives may also be added in the form of dispersion.

In particular, a crosslinking agent is preferably used, because it can provide a cohesive strength, which is related to the durability of the pressure-sensitive adhesive. A polyfunctional compound may be used as a crosslinking agent, examples of which include an organic crosslinking agent and a polyfunctional metal chelate. Examples of the organic crosslinking agent include an epoxy crosslinking agent, an isocyanate crosslinking agent, a carbodiimide crosslinking agent, an imine crosslinking agent, an oxazoline crosslinking agent, an aziridine crosslinking agent, etc. The organic crosslinking agent is preferably an isocyanate crosslinking agent or a carbodiimide crosslinking agent. The polyfunctional metal chelate may comprise a polyvalent metal and an organic compound that is covalently or coordinately bonded to the metal. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. The organic compound has a covalent or coordinate bond-forming atom such as an oxygen atom. Examples of the organic compound include an alkyl ester, an alcohol compound, a carboxylic acid compound, an ether compound, and a ketone compound.

The content of the crosslinking agent in the water-dispersible acryl-based pressure-sensitive adhesive is generally, but not limited to, about 10 parts by weight or less (on a solid basis), based on 100 parts by weight of the (meth)acryl-based polymer (on a solid basis). The content of the crosslinking agent is preferably from 0.01 to 10 parts by weight, more preferably from 0.1 to 5 parts by weight.

The pressure-sensitive adhesive layer 3 of the invention for transparent conductive film is made from the water-dispersible acryl-based pressure-sensitive adhesive. For example, the pressure-sensitive adhesive layer 3 may be formed by a process including applying the water-dispersible acryl-based pressure-sensitive adhesive to a release film or any other material and drying the adhesive using a dryer such as a hot oven to remove water and volatilize excess water-soluble basic component. The pressure-sensitive adhesive layer 3 formed on the release film is transferred to a first transparent plastic film substrate. Alternatively, the pressure-sensitive adhesive layer 3 may be formed by a process including applying the water-dispersible acryl-based pressure-sensitive adhesive to a first transparent plastic film substrate and drying the adhesive to form the pressure-sensitive adhesive layer 3 on the first transparent plastic film substrate. The drying conditions (temperature and time period) are typically from about 80 to about 170° C., preferably from 90 to 140° C., and for 1 to 60 minutes, preferably for 3 to 30 minutes.

The pressure-sensitive adhesive layer 3 maybe formed by any of various methods. Examples include roll coating, kiss roll coating, gravure coating, reverse coating, roll brushing, spray coating, dip roll coating, bar coating, knife coating, air knife coating, curtain coating, lip coating, and extrusion coating with a die coater or the like.

The thickness of the pressure-sensitive adhesive layer 3 is typically from 10 to 100 μm, preferably from 15 to 80 μm, more preferably from 20 to 60 μm. If the pressure-sensitive adhesive layer 3 has a thickness of less than 10 μm, the transparent conductive film with pressure-sensitive adhesive layer may have low adhesion to various types of adherends such as glass, films, and transparent conductive thin films in a touch panel structure, and adhesion between films may also be low in a laminated structure, so that durability may be insufficient at high temperature or high temperature and high humidity. On the other hand, if the pressure-sensitive adhesive layer 3 has a thickness of more than 100 μm, water can be insufficiently removed in the process of applying and drying the water-dispersible acryl-based pressure-sensitive adhesive to form the pressure-sensitive adhesive layer 3, so that air bubbles can remain or thickness irregularities may occur on the surface of the pressure-sensitive adhesive layer 3, which may easily produce a problem with appearance.

The pressure-sensitive adhesive layer 3 maybe exposed. In such a case, the pressure-sensitive adhesive layer 3 may be protected by the release film 5 (separator) until it is actually used.

Examples of the material used to form the release film include a plastic film such as a polyethylene, polypropylene, polyethylene terephthalate, or polyester film, a porous material such as paper, fabric, or nonwoven fabric, and an appropriate thin material such as a net, a foamed sheet, a metal foil, and a laminate thereof. A plastic film is preferably used, because of its good surface smoothness.

Any plastic film capable of protecting the pressure-sensitive adhesive layer may be used, examples of which include a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, and an ethylene-vinyl acetate copolymer film.

The thickness of the release film 5 is generally from about 5 to about 200 μm, preferably from about 5 to about 100 μm. If necessary, the separator may be subjected to a release treatment and an antifouling treatment with a silicone, fluoride, long-chain alkyl, or fatty acid amide release agent, silica powder or the like, or subjected to an antistatic treatment of coating type, kneading and mixing type, vapor-deposition type, or the like. In particular, when the surface of the release film is appropriately subjected to a release treatment such as a silicone treatment, a long-chain alkyl treatment, or a fluorine treatment, the releasability from the pressure-sensitive adhesive layer 3 can be further increased.

The release film 5, which is used for the formation of the pressure-sensitive adhesive 3, may be used as is as a separator for the pressure-sensitive adhesive 3, so that the process can be simplified.

Next, a description is given of other features of the transparent conductive film with pressure-sensitive adhesive layer other than the pressure-sensitive adhesive layer 3.

The first transparent plastic film substrate 1 to be used may be, but not limited to, various transparent plastic films. The plastic film is generally formed of a monolayer film. Examples of the material for the transparent plastic film substrate 1 include polyester resins such as polyethylene terephthalate and polyethylene naphthalate, acetate resins, polyethersulfone resins, polycarbonate resins, polyamide resins, polyimide resins, polyolefin resins, (meth)acrylic resins, polyvinyl chloride resins, polyvinylidene chloride resins, polystyrene resins, polyvinyl alcohol resins, polyarylate resins, and polyphenylene sulfide resins. In particular, polyester resins, polyimide resins, and polyethersulfone resins are preferred.

The film substrate 1 preferably has a thickness of 15 to 200 μm, more preferably 25 to 188 μm. If the thickness of the film substrate 1 is less than 15 μm, the mechanical strength of the film substrate 1 may be insufficient, so that it may be difficult to perform the process of continuously forming the transparent conductive thin film 2 on the film substrate 1 being fed from a roll. If the thickness is more than 200 μm, the amount of introduction of the film substrate 1 may decrease in the process of forming the transparent conductive thin film 2, and the process of removing gas and water maybe hindered, so that the productivity may decrease.

The surface of the film substrate 1 maybe previously subject to sputtering, corona discharge treatment, flame treatment, ultraviolet irradiation, electron beam irradiation, chemical treatment, etching treatment such as oxidation, or undercoating treatment such that the adhesion of the transparent conductive thin film 2 or the undercoat layer 5 formed thereon to the transparent plastic film substrate 1 can be improved. If necessary, the film substrate 1 may also be subjected to dust removing or cleaning by solvent cleaning, ultrasonic cleaning or the like, before the transparent conductive thin film 2 or the undercoat layer 5 is formed.

Examples of materials, but are not limited to, are preferably used to form the transparent conductive thin film 2 include, metal oxides such as tin oxide-doped indium oxide and antimony-doped tin oxide.

A metal oxide may be used to form the transparent conductive thin film 2. The metal oxide is preferably tin oxide-doped indium oxide. Such a metal oxide preferably contains 80 to 99% by weight of indium oxide and 1 to 20% by weight of tin oxide.

The thickness of the transparent conductive thin film 2 is preferably, but not limited to, 10 nm or more, in order that it may form a highly-conductive continuous coating film with a surface resistance of 1×10³ Ω/square or less. If the thickness is too large, a reduction in transparency and so on may occur. Therefore, the thickness is preferably from 15 to 35 nm, more preferably from 20 to 30 nm. If the thickness is less than 15 nm, the surface electric resistance may be too high, and it may be difficult to form a continuous coating film. If the thickness is more than 35 nm, a reduction in transparency may occur.

The transparent conductive thin film 2 may be formed using known conventional methods, while the methods are not particularly limited. Examples of such methods include vacuum deposition, sputtering, and ion plating. Any appropriate method may be used depending on the required film thickness.

The undercoat layer 5 may be made of an inorganic material, an organic material or a mixture of an inorganic material and an organic material. Examples of the inorganic material include NaF (1.3), Na₃AlF₆ (1.35), LiF (1.36), MgF₂ (1.38), CaF₂ (1.4), BaF₂ (1.3), SiO₂ (1.46), LaF₃ (1.55), CeF₃ (1.63), and Al₂O₃ (1.63), wherein each number inside the parentheses is the refractive index of each material. In particular, SiO₂, MgF₂, Al₂O₃, or the like is preferably used. In particular, SiO₂ is preferred. Besides the above, a complex oxide containing about 10 to about 40 parts by weight of cerium oxide and about 0 to about 20 parts by weight of tin oxide based on 100 parts by weight of the indium oxide may also be used.

The undercoat layer made of an inorganic material maybe form with a dry process such as vacuum deposition, sputtering or ion plating, a wet process (coating process), or the like. SiO₂ is preferably used as the inorganic material to form the undercoat layer as described above. In a wet process, a silica sol or the like may be applied to form a SiO₂ film.

Examples of the organic material include acrylic resins, urethane resins, melamine resins, alkyd resins, siloxane polymers, and organosilane-based condensates. At least one of these organic materials may be used. In particular, a thermosetting resin including a mixture composed of a melamine resin, an alkyd resin and an organosilane condensate is preferably used as the organic material.

When a plurality of undercoat layers 5 are formed, the first undercoat layer from the transparent plastic film substrate 1 is preferably made of an organic material, and the undercoat layer most distant from the transparent plastic film substrate 1 is preferably made of an inorganic material, in view of the processability of the resulting transparent conductive film with the pressure-sensitive adhesive layer. When two undercoat layers 5 are formed, therefore, the first undercoat layer from the transparent plastic film substrate 1 is preferably made of an organic material, and the second undercoat layer is preferably made of an inorganic material.

The thickness of the undercoat layer 5 is generally, but not limited to, from about 1 to about 300 nm, preferably from 5 to 300 nm, in view of optical design and the effect of preventing the release of an oligomer from the film substrate 1. When two or more undercoat layers 5 are provided, the thickness of each layer may be from about 5 to about 250 nm, preferably from 10 to 250 nm.

Any appropriate material capable of forming a transparent film may be used to form the oligomer blocking layer 6, and such a material may be an inorganic material, an organic material, or a composite thereof. The oligomer blocking layer preferably has a thickness of 0.01 to 20 μm. The oligomer blocking layer 5 is often formed using a coating method with a coater, a spraying method, a spin coating method, an in-line coating method, or the like, while it may be formed using any other method such as vacuum deposition, sputtering, ion plating, spray thermal decomposition, chemical plating, or electroplating. The coating method may be performed using a resin component such as polyvinyl alcohol-based resin, acrylic resin, urethane resin, melamine resin, UV-curable resin, or epoxy resin, or a mixture of any of the above resins and inorganic particles of alumina, silica, mica, or the like. Alternatively, a polymer substrate may be formed by coextrusion of two or more layers so that a component of the substrate can have the function of the blocking layer 5. Other methods such as vacuum deposition, sputtering, ion plating, spray thermal decomposition, chemical plating, and electroplating may be performed using a metal such as gold, silver, platinum, palladium, copper, aluminum, nickel, chromium, titanium, iron, cobalt, tin, or any alloy thereof, a metal oxide such as indium oxide, tin oxide, titanium oxide, cadmium oxide, or any mixture thereof, or any other metal compound such as a metal iodide.

Among the examples of the oligomer blocking layer 6-forming material, polyvinyl alcohol-based resin is particularly suited for applications of the invention, because it has a high oligomer-blocking function. Polyvinyl alcohol-based resin includes polyvinyl alcohol as a principal component, and in general, it preferably has a polyvinyl alcohol content in the range of 30 to 100% by weight. When it has a polyvinyl content of 30% by weight or more, it can be highly effective in preventing oligomer precipitation. Water-borne resin such as polyester or polyurethane may be mixed with polyvinyl alcohol. The degree of polymerization of polyvinyl alcohol is generally, but not limited to, 300 to 4,000, and such polyvinyl alcohol is advantageous for applications. The degree of saponification of polyvinyl alcohol is generally, but not limited to, 70% by mole or more, preferably 99.9% by mole or more. Polyvinyl alcohol-based resin may be used in combination with a crosslinking agent. Examples of such a crosslinking agent include various compounds such as methylolated or alkylolated urea compounds, melamine compounds, guanamine compounds, acrylamide compounds, and polyamide compounds, epoxy compounds, aziridine compounds, blocked isocyanate, silane coupling agents, titanate coupling agents, and zirco-aluminate coupling agents. Any of these crosslinking components may be previously bonded to a binder polymer. Inorganic particles may also be added for the purpose of improving anchoring properties or lubricity, examples of which include silica, alumina, kaolin, calcium carbonate, titanium oxide, and barium salt particles. If necessary, an antifoaming agent, an application conditioner, a thickener, an organic lubricant, organic polymer particles, an antioxidant, an ultraviolet absorbing agent, a foaming agent, a dye, or any other additive may also be added.

The transparent conductive film with the pressure-sensitive adhesive layer of the invention may be produced by any method capable of forming the structure described above. A general production method may include forming the transparent conductive thin film 2 (and the undercoat layer 5 in some cases) on one side of the transparent plastic film substrate 1 to form the transparent conductive film and then forming the pressure-sensitive adhesive layer 3 on the other side of the transparent plastic film substrate 1. The pressure-sensitive adhesive layer 3 may be formed directly on the transparent plastic film substrate 1. Alternatively, the pressure-sensitive adhesive layer 3 may be formed on the release film 4 and then attached to the transparent plastic film substrate 1. The latter process is more advantageous in terms of productivity, because it allows continuous formation of the pressure-sensitive adhesive layer 3 on the film substrate 1 used in the form of a roll.

As shown in FIG. 3, a second transparent plastic film substrate 1′ may be further bonded to the pressure-sensitive adhesive layer 3 of the transparent conductive film with pressure-sensitive adhesive layer to form a transparent conductive laminate.

A second transparent plastic film substrate 1′ may be bonded by a process including forming the pressure-sensitive adhesive layer 3 on the second transparent plastic film substrate 1′ and then attaching the film substrate 1 thereto or a process including forming the pressure-sensitive adhesive layer 3 contrarily on the film substrate 1 and then attaching the second transparent plastic film substrate 1′ thereto. The latter process is more advantageous in terms of productivity, because it allows continuous formation of the pressure-sensitive adhesive layer 3 on the film substrate 1 used in the form of a roll.

The second transparent plastic film substrate 1′ may be a single-layer structure as shown in FIG. 3. Alternatively, two or more second transparent plastic film substrates 1′ maybe laminated together with a transparent pressure-sensitive adhesive layer(s) to form a composite structure, which can increase the mechanical strength and other properties of the entire laminate. While FIG. 3 shows a case where the second transparent plastic film substrate 1′ is bonded to the transparent conductive film with the pressure-sensitive adhesive layer shown in FIG. 1, a transparent conductive laminate may be similarly formed by bonding the second transparent plastic film substrate 1′ to the transparent conductive film with the pressure-sensitive adhesive layer shown in FIG. 2.

A description will be given of a case where a single-layer structure is used as the second transparent plastic film substrate 1′. When the transparent conductive laminate is required to be flexible even after the single-layered second transparent plastic film substrate 1′ is bonded, a plastic film with a thickness of about 6 to about 300 μm is generally used as the second transparent plastic film substrate 1′. When such flexibility is not particularly required, a glass plate or plastic film or plate with a thickness of about 0.05 to about 10 mm is generally used as the second transparent substrate 1′. The plastic material may be the same as that of the film substrate 1. When a multi-layer structure is used as the second transparent plastic film substrate 1′, the same thickness as described above is preferably used.

In the transparent conductive laminate, a hard coat layer may be provided on one or both sides of the second transparent plastic film substrate 1′. In FIG. 4, a hard coat layer 7 is provided on one side (which is not bonded to the pressure-sensitive adhesive layer 3) of the second transparent plastic film substrate 1′. The hard coat layer 7 maybe formed by subjecting the second transparent plastic film substrate to a hard coating process. For example, the hard coating process may be performed by a method including applying a hard resin such as an acrylic-urethane resin or a siloxane resin and curing the hard resin. The hard coating process may include adding a silicone resin or the like to the hard resin such as the acrylic-urethane resin or the siloxane resin to form a roughened surface, so that a non-glare surface capable of preventing reflections by a mirror effect in practical applications such as touch panels can be formed at the same time.

A too thin hard coat layer 7 may have insufficient hardness, while a too thick hard coat layer may be cracked. Also in view of the property of preventing curling and the like, the thickness of the hard coat layer is preferably from about 0.1 to about 30 μm.

In addition to the hard coat layer 7, if necessary, an anti-glare or anti-reflection layer for improving the visibility may also be formed on the outer surface (which is not bonded to the pressure-sensitive adhesive layer 3) of the second transparent plastic film substrate.

In the process of producing a touch panel, the transparent conductive film with pressure-sensitive adhesive layer or the transparent conductive laminate according to the invention is preferably used as a touch panel-forming electrode plate. The invention is applicable to various types of touch panel, such as optical, ultrasonic, capacitance, and resistive touch panels. In particular, the invention is preferably applied to capacitance touch panels.

A capacitance touch panel generally includes a transparent conductive film that has a transparent conductive thin film in a specific pattern and is formed over the surface of a display unit. Although the transparent conductive thin film 2 is not patterned in FIGS. 1 to 4, the transparent conductive thin film 2 to be used may be appropriately patterned, and such a patterned transparent conductive film is conveniently used to form a laminate.

### EXAMPLES

Hereinafter, the invention is described in more detail with reference to the examples, which however are not intended to limit the gist of the invention. In each example, “parts” and “%” are all by weight.

### <Average Particle Size>

The average particle size of the (meth)acryl-based polymer in the water-dispersible acryl-based pressure-sensitive adhesive (emulsion) formed using the aqueous dispersion of each example was measured using LS13320 manufactured by Beckman Coulter, Inc.

### Example 1

### (Preparation of Aqueous Dispersion)

To a vessel were added 1,000 parts of butyl acrylate, 50 parts of acrylic acid, 23 parts of mono[poly(propylene oxide)methacrylate]phosphate ester (5.0 in average degree of polymerization of propylene oxide), and 0.34 parts of 3-methacryloyloxypropyl-triethoxysilane (KBM-503, manufactured by Shin-Etsu Chemical Co., Ltd.) as raw materials and mixed to form a monomer mixture. Subsequently, 13 parts of AQUALON HS-10 (manufactured by Dai-ichi Kogyo Seiyaku Co., Ltd.) as a reactive emulsifying agent and 360 parts of ion-exchanged water were added to 600 parts of the monomer mixture prepared with the above composition, and stirred at 7,000 rpm for 3 minutes using a homogenizer (manufactured by PRIMIX Corporation), so that a monomer emulsion was obtained.

Subsequently, 200 parts of the monomer emulsion prepared as described above and 350 parts of ion-exchanged water were added to a reaction vessel equipped with a condenser tube, a nitrogen-introducing tube, a thermometer, a dropping funnel, and a stirring blade. Subsequently, after the space in the reaction vessel was replaced with nitrogen sufficiently, 0.1 parts of ammonium persulfate was added to the vessel, and polymerization was carried out at 65° C. for 2 hour. Subsequently, the remaining part of the monomer emulsion was added dropwise to the reaction vessel over 3 hours, and then polymerization was carried out for 3 hours. Subsequently, while the atmosphere was replaced with nitrogen, polymerization was further carried out at 75° C. for 5 hours, so that a water-dispersible acryl-based pressure-sensitive adhesive (emulsion) with a solids content of 42% was obtained. The (meth)acryl-based polymer in the aqueous dispersion (emulsion) had an average particle size of 0.08 μm.

### (Preparation of Water-Dispersible Acryl-Based Pressure-Sensitive Adhesive)

Subsequently, 3 parts of 10% ammonia water was added to 100 parts of the aqueous dispersion (emulsion), and distilled water was further added thereto to adjust the solid concentration to 38%, so that a water-dispersible acryl-based pressure-sensitive adhesive was obtained.

### (Formation of Pressure-Sensitive Adhesive Layer for Transparent Conductive Film)

The water-dispersible acryl-based pressure-sensitive adhesive was applied to a release film (Diafoil MRF-38, manufactured by Mitsubishi Chemical Polyester Co., Ltd., a polyethylene terephthalate backing) with an applicator so that a 23 μm thick coating could be formed after drying, and then the coating was dried at 130° C. for 10 minutes in a hot air circulation oven to form a pressure-sensitive adhesive layer.

### (Formation of Oligomer Blocking Layer)

An aqueous solution of polyvinyl alcohol resin was applied to one surface of a 25 μm thick polyethylene terephthalate film (hereinafter referred to as “PET film”), which is film substrate, so that a 30 μm thick coating could be formed, and the coating was dried to form an oligomer blocking layer.

### (Formation of Undercoat Layer)

A 180 nm-thick first undercoat layer was formed on the other side of the PET film, which has the oligomer blocking layer, using a thermosetting resin composed of a melamine resin, an alkyd resin and an organosilane condensate (2:2:1 in weight ratio). SiO₂ was then vacuum-deposited on the first undercoat layer by electron-beam heating at a degree of vacuum of 1.33×10⁻² to 2.67×10⁻² Pa to form a 40 nm-thick second undercoat layer (SiO₂ film).

### (Formation of Transparent Conductive Thin Film)

A 20 nm-thick ITO film was then formed on the second undercoat layer by a reactive sputtering method in a 5.33×10⁻² Pa atmosphere of 80% argon gas and 20% oxygen gas using a material of 90% by weight of indium oxide and 10% by weight of tin oxide, so that a transparent conductive film was obtained. The ITO film was amorphous.

(Preparation of Transparent Conductive Film with Pressure-Sensitive Adhesive Layer)

The transparent conductive film (the surface on which no ITO film was formed) was bonded to the pressure-sensitive adhesive layer provided on the release film, so that a transparent conductive film with the pressure-sensitive adhesive layer was obtained.

### Example 2

A transparent conductive film with pressure-sensitive adhesive layer was prepared as in Example 1, except that the added amount of 10% ammonia water was changed from 3 parts to 10 parts in the preparation of the water-dispersible acryl-based pressure-sensitive adhesive and that the drying conditions in the formation of the pressure-sensitive adhesive layer were changed from 130° C. for 10 minutes to 90° C. for 10 minutes.

### Example 3

A transparent conductive film with pressure-sensitive adhesive layer was prepared as in Example 1, except that the added amount of 10% ammonia water was changed from 3 parts to 0.5 parts in the preparation of the water-dispersible acryl-based pressure-sensitive adhesive.

### Example 4

A transparent conductive film with pressure-sensitive adhesive layer was prepared as in Example 1, except that the thickness of the pressure-sensitive adhesive layer was changed from 23 μm to 60 μm in the formation of the pressure-sensitive adhesive layer and that the thickness of the PET film was changed from 25 μm to 50 μm in the formation of the oligomer blocking layer.

### Example 5

A transparent conductive film with pressure-sensitive adhesive layer was prepared as in Example 1, except that the thickness of the pressure-sensitive adhesive layer was changed from 23 μm to 80 μm in the formation of the pressure-sensitive adhesive layer and that the thickness of the PET film was changed from 25 μm to 50 μm in the formation of the oligomer blocking layer.

### Example 6

A transparent conductive film with pressure-sensitive adhesive layer was prepared as in Example 1, except that the thickness of the pressure-sensitive adhesive layer was changed from 23 μm to 10 μm in the formation of the pressure-sensitive adhesive layer.

### Example 7

A transparent conductive film with pressure-sensitive adhesive layer was prepared as in Example 1, except that the amount of acrylic acid used was changed from 50 parts to 10 parts in the preparation of the aqueous dispersion.

### Example 8

A transparent conductive film with pressure-sensitive adhesive layer was prepared as in Example 1, except that the amount of acrylic acid used was changed from 50 parts to 78 parts in the preparation of the aqueous dispersion.

### Example 9

A transparent conductive film with pressure-sensitive adhesive layer was prepared as in Example 1, except that 0.3 parts of diethylenetriamine was used instead of 3 parts of 10% ammonia water in the preparation of the water-dispersible acryl-based pressure-sensitive adhesive.

### Example 10

A transparent conductive film with pressure-sensitive adhesive layer was prepared as in Example 1, except that the amount of mono [poly (propylene oxide) methacrylate] phosphate ester (5.0 in average degree of polymerization of propylene oxide) was changed from 23 parts to 7 parts in the preparation of the aqueous dispersion.

### Example 11

A transparent conductive film with pressure-sensitive adhesive layer was prepared as in Example 1, except that the amount of mono [poly (propylene oxide) methacrylate] phosphate ester (5.0 in average degree of polymerization of propylene oxide) was changed from 23 parts to 50 parts in the preparation of the aqueous dispersion.

### Example 12

A transparent conductive film with pressure-sensitive adhesive layer was prepared as in Example 1, except that 10 parts of an aqueous solution of 10% sodium hydroxide was added instead of 33 parts of 10% ammonia water in the preparation of the water-dispersible acryl-based pressure-sensitive adhesive and that the formation of the pressure-sensitive adhesive layer was so modified that an 80 μm thick coating could be formed after drying.

### Comparative Example 1

A transparent conductive film with pressure-sensitive adhesive layer was prepared as in Example 1, except that the added amount of 10% ammonia water was changed from 3 parts to 0.2 parts in the preparation of the water-dispersible acryl-based pressure-sensitive adhesive and that the drying conditions in the formation of the pressure-sensitive adhesive layer were changed from 130° C. for 10 minutes to 150° C. for 20 minutes.

### Comparative Example 2

A transparent conductive film with pressure-sensitive adhesive layer was prepared as in Example 1, except that the thickness of the pressure-sensitive adhesive layer was changed from 23 μm to 8 μm in the formation of the pressure-sensitive adhesive layer.

### Comparative Example 3

A transparent conductive film with pressure-sensitive adhesive layer was prepared as in Example 1, except that the thickness of the pressure-sensitive adhesive layer was changed from 23 μm to 110 μm in the formation of the pressure-sensitive adhesive layer.

### Comparative Example 4

A transparent conductive film with pressure-sensitive adhesive layer was prepared as in Example 1, except that the amount of acrylic acid used was changed from 50 parts to 5 parts in the preparation of the aqueous dispersion.

### Comparative Example 5

A transparent conductive film with pressure-sensitive adhesive layer was prepared as in Example 1, except that the amount of acrylic acid used was changed from 50 parts to 100 parts in the preparation of the aqueous dispersion.

### Comparative Example 6

A transparent conductive film with pressure-sensitive adhesive layer was prepared as in Example 1, except that 20 parts of an aqueous solution of 10% sodium hydroxide was added instead of 33 parts of 10% ammonia water in the preparation of the water-dispersible acryl-based pressure-sensitive adhesive and that the formation of the pressure-sensitive adhesive layer was so modified that a 100 μm thick coating could be formed after drying. The viscosity of the coating liquid significantly increased, so that a good coating appearance was not obtained.

### Comparative Example 7

### (Preparation of Acryl-Based Polymer Solution)

To a vessel were added 100 parts of butyl acrylate, 5 parts of acrylic acid, 0.1 parts of 2-hydroxyethyl acrylate, 0.2 parts of 2,2′-azobisisobutyronitrile as a polymerization initiator, and 300 parts of ethyl acetate as a polymerization solvent. After the air was sufficiently replaced by nitrogen, the mixture in the vessel was subjected to a polymerization reaction for 6 hours, while stirred under a nitrogen gas stream and kept at about 60° C., so that an acryl-based polymer solution with a solid concentration of 24% was obtained. The acryl-based polymer had a weight average molecular weight of 2,000,000.

### (Preparation of Solvent-Type Acryl-Based Pressure-Sensitive Adhesive)

To 100 parts, on a solid basis, of the acryl-based polymer solution were added 3.2 parts of an aromatic isocyanate crosslinking agent (CORONATE L, manufactured by NIPPON POLYURETHANE INDUSTRY CO., LTD.), 0.01 parts of a silane coupling agent (KBM403, manufactured by Shin-Etsu Chemical Co., Ltd.), and ethyl acetate, and uniformly mixed and stirred, so that an acryl-based pressure-sensitive adhesive solution (11% in solid concentration) was obtained.

### (Formation of Pressure-Sensitive Adhesive Layer)

The acryl-based pressure-sensitive adhesive solution was applied onto a separator made of a release-treated polyethylene terephthalate film (38 μm in thickness) and heated at 155° C. for 1 minute to form a pressure-sensitive adhesive layer with a post-drying thickness of 23 μm.

(Preparation of Transparent Conductive Film with Pressure-Sensitive Adhesive Layer)

An oligomer blocking layer, an undercoat layer, a transparent conductive thin film, and a transparent conductive film with pressure-sensitive adhesive layer were formed as in Example 1, except that the resulting pressure-sensitive adhesive layer was used.

The transparent conductive film with pressure-sensitive adhesive layer obtained in the examples and the comparative examples were evaluated as described below. Table 1 shows the results. Table 1 also shows the contents of the carboxyl group-containing monomer (acrylic acid) and the phosphate group-containing monomer in the acryl-based polymer used in each of the examples and the comparative examples, the added amount of the water-soluble basic component, the thickness of the pressure-sensitive adhesive layer, the drying conditions, and the thickness of the film substrate.

### <Measurement of the Amount of Water-Soluble Basic Component>

Each transparent conductive film with pressure-sensitive adhesive layer was cut into apiece of 9 cm×9 cm. After the release film was peeled off, the cut piece was subjected to boiling extraction in pure water at 120° C. for 1 hour. The amount of the water-soluble basic component (such as ammonium ions) in the extract was determined using ion chromatography (DX-500, manufactured by Dionex Corporation). Five samples were measured, and the average was calculated from the resulting values and converted into a value per 1 cm², which was determined to be the amount of the water-soluble basic component.

### <Coating Appearance>

The pressure-sensitive adhesive layer of each transparent conductive film with pressure-sensitive adhesive layer was visually evaluated for appearance according to the following criteria.
◯: No defects (streaks, unevenness, or air bubbles) are observed.
33 : Defects (streaks, unevenness, or air bubbles) are observed.

### <Corrosion Test>

Two transparent conductive films with pressure-sensitive adhesive layer were prepared. One of the films was cut into apiece of 15 mm×15 mm (hereinafter referred to as sheet 1), and the other into a piece of 8 mm×8 mm (hereinafter referred to as sheet 2). The surface of the pressure-sensitive adhesive layer of sheet 2 was placed on the ITO film of sheet 1 to form a laminate sample. The resistance of the ITO film of sheet 1 in the sample was measured using a hole tester (this resistance is referred to as the pre-storage resistance). The sample was then allowed to stand in an atmosphere at 60° C. and 95% RH for 500 hours. After the storage, the resistance of the ITO film of sheet 1 in the sample was measured in the same way (this resistance is referred to as the post-storage resistance). The rate of resistance increase between before and after the storage of the sample in the atmosphere was calculated from the results.

The rate (%) of resistance increase=(the post-storage resistance/the pre-storage resistance)×100

The lower rate of resistance increase is the better. When the rate of resistance increase is 130% or less, it can be determined that the result of the corrosion test is satisfactory, and this case is indicated by the evaluation mark “◯.” The case where the rate was more than 130% is indicated by the evaluation mark “×”.

### <Durability>

Three transparent conductive films with pressure-sensitive adhesive layer were prepared and heated at 140° C. for 90 minutes. One of the transparent conductive films with pressure-sensitive adhesive layer was provided, and its pressure-sensitive adhesive layer side was placed on a glass substrate to form a laminate. Subsequently, the other two transparent conductive films with pressure-sensitive adhesive layer were sequentially laminated in such a manner that each pressure-sensitive adhesive layer side was bonded to the ITO film of the transparent conductive film with pressure-sensitive adhesive layer already placed, so that a sample was obtained. The sample was allowed to stand in an atmosphere at 60° C. and 95% RH for 500 hours and in an atmosphere at 80° C. for 500 hours, respectively. After the storage, foaming and peeling between the glass and the pressure-sensitive adhesive layer and between the first (or second) and second (or third) transparent conductive films with pressure-sensitive adhesive layer in the sample were visually evaluated according to the following criteria.
◯: No foaming or peeling is observed.
×: Foaming or peeling is observed.

TABLE 1

| | Acryl-based polymer | | | | | | | |
|---|---|---|---|---|---|---|---|---|
| | Carboxyl | Phosphate | Water-soluble basic component | | | Pressure-sensitive adhesive layer | | |
| | group- | group- | | | 10% sodium | | | Amount |
| | containing | containing | 10% | | hydroxide | | | (ng/cm²) of |
| | monomer | monomer | ammonia | Diethylene | aqueous | | | water-soluble |
| | content | content | water | triamine | solution | Thickness | Drying | basic |
| | (parts) | (parts) | (parts) | (parts) | (parts) | (μm) | conditions | component |
| Example 1 | 5 | 2.3 | 3 | — | — | 23 | 130° C. for 10 | 1000 |
| | | | | | | | minutes | |
| Example 2 | 5 | 2.3 | 10 | — | — | 23 | 90° C. for 10 | 48000 |
| | | | | | | | minutes | |
| Example 3 | 5 | 2.3 | 0.5 | — | — | 23 | 130° C. for 10 | 250 |
| | | | | | | | minutes | |
| Example 4 | 5 | 2.3 | 3 | — | — | 60 | 130° C. for 10 | 2100 |
| | | | | | | | minutes | |
| Example 5 | 5 | 2.3 | 3 | — | — | 80 | 130° C. for 10 | 7600 |
| | | | | | | | minutes | |
| Example 6 | 5 | 2.3 | 3 | — | — | 10 | 130° C. for 10 | 510 |
| | | | | | | | minutes | |
| Example 7 | 1 | 2.3 | 3 | — | — | 23 | 130° C. for 10 | 730 |
| | | | | | | | minutes | |
| Example 8 | 7.8 | 2.3 | 3 | — | — | 23 | 130° C. for 10 | 2300 |
| | | | | | | | minutes | |
| Example 9 | 5 | 2.3 | — | 0.3 | — | 23 | 130° C. for 10 | 5800 |
| | | | | | | | minutes | |
| Example 10 | 5 | 0.7 | 3 | — | — | 23 | 130° C. for 10 | 1200 |
| | | | | | | | minutes | |
| Example 11 | 5 | 5 | 3 | — | — | 23 | 130° C. for 10 | 1220 |
| | | | | | | | minutes | |
| Example 12 | 5 | 2.3 | — | — | 10 | 80 | 130° C. for 10 | 245000 |
| | | | | | | | minutes | |
| Comparative | 5 | 2.3 | 0.2 | — | — | 23 | 150° C. for 20 | 160 |
| Example 1 | | | | | | | minutes | |
| Comparative | 5 | 2.3 | 3 | — | — | 8 | 130° C. for 10 | 2100 |
| Example 2 | | | | | | | minutes | |
| Comparative | 5 | 2.3 | 3 | — | — | 110 | 130° C. for 10 | 7100 |
| Example 3 | | | | | | | minutes | |
| Comparative | 0.5 | 2.3 | 3 | — | — | 23 | 130° C. for 10 | 400 |
| Example 4 | | | | | | | minutes | |
| Comparative | 10 | 2.3 | 3 | — | — | 23 | 130° C. for 10 | 1200 |
| Example 5 | | | | | | | minutes | |
| Comparative | 5 | 2.3 | — | — | 20 | 100 | 130° C. for 10 | 510000 |
| Example 6 | | | | | | | minutes | |
| Comparative | 5 | — | — | — | — | 23 | 155° C. for 1 | 0 |
| Example 7 | | | | | | | minute | |

| | | Evaluations | | | | |
|---|---|---|---|---|---|---|
| | | | | | Durability | |
| | Film | | | | | 60° C./95% |
| | substrate | | Corrosion | | 80° C. for | RH for |
| | Thickness | Coating | Increase | | 500 | 500 |
| | (μm) | appearance | rate (%) | Result | hours | hours |
| Example 1 | 25 | ◯ | 111 | ◯ | ◯ | ◯ |
| Example 2 | 25 | ◯ | 102 | ◯ | ◯ | ◯ |
| Example 3 | 25 | ◯ | 128 | ◯ | ◯ | ◯ |
| Example 4 | 50 | ◯ | 102 | ◯ | ◯ | ◯ |
| Example 5 | 50 | ◯ | 104 | ◯ | ◯ | ◯ |
| Example 6 | 25 | ◯ | 121 | ◯ | ◯ | ◯ |
| Example 7 | 25 | ◯ | 120 | ◯ | ◯ | ◯ |
| Example 8 | 25 | ◯ | 100 | ◯ | ◯ | ◯ |
| Example 9 | 25 | ◯ | 102 | ◯ | ◯ | ◯ |
| Example 10 | 25 | ◯ | 115 | ◯ | ◯ | ◯ |
| Example 11 | 25 | ◯ | 113 | ◯ | ◯ | ◯ |
| Example 12 | 25 | ◯ | 101 | ◯ | ◯ | ◯ |
| Comparative | 25 | ◯ | 150 | X | ◯ | ◯ |
| Example 1 | | | | | | |
| Comparative | 25 | ◯ | 124 | ◯ | X | X |
| Example 2 | | | | | | |
| Comparative | 25 | X | 107 | ◯ | X | ◯ |
| Example 3 | | | | | | |
| Comparative | 25 | X | 120 | ◯ | X | X |
| Example 4 | | | | | | |
| Comparative | 25 | X | 147 | X | X | ◯ |
| Example 5 | | | | | | |
| Comparative | 25 | X | 101 | ◯ | X | X |
| Example 6 | | | | | | |
| Comparative | 25 | ◯ | 175 | X | ◯ | ◯ |
| Example 7 | | | | | | |

In Table 1, the carboxyl group-containing monomer content and the phosphate group-containing monomer content are based on 100 parts of butyl acrylate. The added amount of the water-soluble basic component is indicated based on 100 parts by weight of the aqueous dispersion (emulsion).

### DESCRIPTION OF REFERENCE SIGNS

In the drawings, reference sign 1 represents a first transparent plastic film substrate, 1′ a second transparent plastic film substrate, 2 a transparent conductive thin film layer, 3 a pressure-sensitive adhesive layer, 4 a release film, 5 an undercoat layer, 6 an oligomer blocking layer, and 7 a hard coat layer.

1. A pressure-sensitive adhesive layer for transparent conductive film, wherein
the pressure-sensitive adhesive layer has a thickness of 10 μm to 100 μm, and
the pressure-sensitive adhesive layer is made from a water-dispersible acryl-based pressure-sensitive adhesive that is an aqueous dispersion containing a water-dispersible (meth)acryl-based polymer and a water-soluble basic component, wherein the water-dispersible (meth)acryl-based polymer comprises 100 parts by weight of an alkyl(meth)acrylate with an alkyl group of 4 to 14 carbon atoms, as a monomer unit, and 1 to 8 parts by weight of a carboxyl group-containing monomer as a copolymerized monomer unit, and
the pressure-sensitive adhesive layer contains 200 ng to 500,000 ng of the water-soluble basic component per 1 cm² as determined by measurement of the pressure-sensitive adhesive layer.

2. The pressure-sensitive adhesive layer for transparent conductive film according to claim 1, which contains more than 2,000 ng of the water-soluble basic component per 1 cm² as determined by measurement of the pressure-sensitive adhesive layer.

3. The pressure-sensitive adhesive layer for transparent conductive film according to claim 1, wherein the water-soluble basic component is ammonia.

4. The pressure-sensitive adhesive layer for transparent conductive film according to claim 1, wherein the water-dispersible (meth)acryl-based polymer further comprises 0.5 to 5 parts by weight of a phosphate group-containing monomer as a monomer unit based on 100 parts by weight of the alkyl(meth)acrylate.

5. The pressure-sensitive adhesive layer for transparent conductive film according to claim 1, which is for use on a transparent conductive film of a capacitance touch panel.

6. A transparent conductive film with pressure-sensitive adhesive layer, comprising:
a first transparent plastic film substrate;
a transparent conductive thin film formed of a metal oxide on one surface of the substrate; and
the pressure-sensitive adhesive layer according to claim 1 provided on another surface of the first transparent plastic film substrate.

7. The transparent conductive film with pressure-sensitive adhesive layer according to claim 6, further comprising at least one undercoat layer, wherein the transparent conductive thin film is provided on the first transparent plastic film substrate with the undercoat layer interposed therebetween.

8. The transparent conductive film with pressure-sensitive adhesive layer according to claim 6, further comprising an oligomer blocking layer, wherein the pressure-sensitive adhesive layer is provided on the first transparent plastic film substrate with the oligomer blocking layer interposed therebetween.

9. The transparent conductive film with pressure-sensitive adhesive layer according to claim 6, which is for use in a capacitance touch panel.

10. A transparent conductive laminate, comprising:
the transparent conductive film with pressure-sensitive adhesive layer according to claim 6; and
a second transparent plastic film substrate bonded to the pressure-sensitive adhesive layer of the transparent conductive film with pressure-sensitive adhesive layer.

11. The transparent conductive laminate according to claim 10, which is for use in a capacitance touch panel.

12. A touch panel, comprising an electrode plate comprising the transparent conductive film with pressure-sensitive adhesive layer according to claim 6.

13. The touch panel according to claim 12, which is for use in a capacitance touch panel.

14. A touch panel, comprising an electrode plate comprising the transparent conductive laminate according to claim 10.

15. The touch panel according to claim 14, which is for use in a capacitance touch panel.
